(19) United States
(12) Patent Application Publication
(10) Pub. No.: US 2026/0182199 A1
(43) Pub. Date: Jun. 25, 2026

(54) Display Apparatus

(71) Applicant: LG Display Co., Ltd., Seoul (KR)

(72) Inventors: Yong-Ku Lee, Paju-si (KR); Ara Yoon, Paju-si (KR); DaeHeung Lee, Paju-si (KR); JinWoo Hong, Paju-si (KR); YoungBok Lee, Paju-si (KR)

(21) Appl. No.: 19/296,768

(22) Filed: Aug. 11, 2025

(30) Foreign Application Priority Data
Dec. 19, 2024 (KR) 10-2024-0190882

(51) Int. Cl. H10K 59/40; H10K 59/179; H10K 59/80

(52) U.S. Cl. CPC H10K 59/40; H10K 59/179; H10K 59/879

(57) ABSTRACT

A display apparatus comprises a substrate having a plurality of sub-pixels; a circuit element layer disposed on the substrate; an organic light-emitting element disposed on the circuit element layer; an electrode pattern disposed on the organic light-emitting element; wherein the electrode pattern includes a protrusion portion and a concave portion that are alternately disposed, and the electrode pattern includes a first electrode pattern disposed on one side of one of the plurality of sub-pixels and a second electrode pattern disposed on the other side of the one of the sub-pixels.

### CROSS-REFERENCE TO RELATED APPLICATIONS

This application claims the benefit of priority of the Korean Patent Application No. 10-2024-0190882 filed on Dec. 19, 2024, which is hereby incorporated by reference as if fully set forth herein.

### BACKGROUND

### Field of the Invention

The present disclosure relates to a display apparatus, and more particularly, for example, without limitation, to a display apparatus with improved brightness difference according to viewing angle.

### Discussion of the Related Art

As the information society develops, the demand for display apparatuses for displaying images is increasing in various forms. Accordingly, various display apparatuses such as liquid crystal displays (LCDs), plasma display panels (PDPs), and organic light emitting displays (OLEDs) are being utilized recently.

Among display apparatuses, organic light-emitting displays are self-luminous, and have superior viewing angles and contrast ratios compared to liquid crystal displays (LCDs). They do not require a separate backlight, so they can be made thin and light, and have the advantage of low power consumption. In addition, organic light-emitting displays can be driven by low DC voltage, have a fast response speed, and have the advantage of low manufacturing costs.

The description provided in the discussion of the related art section should not be assumed to be prior art merely because it is mentioned in or associated with that section. The discussion of the related art section may include information that describes one or more aspects of the subject technology, and the description in this section does not limit the present disclosure.

### SUMMARY

The inventors of the present application found that, in organic light-emitting displays, pixel shrinkage occurs due to high-temperature deterioration driving, in which the pixel size decreases or the display area decreases. This pixel shrinkage phenomenon causes a difference in brightness depending on the viewing angle between the deteriorated area and the non-deteriorated area.

Recently, research has been continuously conducted to improve the difference in brightness according to the viewing angle caused by the pixel shrinkage phenomenon.

One exemplary embodiment of the present disclosure is to provide a display apparatus in which the difference in brightness according to the viewing angle between a deteriorated area and a non-deteriorated area due to pixel shrinkage phenomenon is improved by controlling the shape of an electrode pattern.

In order to achieve the above-described technical problem, one exemplary embodiment of the present disclosure provides a display apparatus comprising: a substrate having a plurality of sub-pixels; a circuit element layer disposed on the substrate; an organic light-emitting element disposed on the circuit element layer; an electrode pattern disposed on the organic light-emitting element, wherein the electrode pattern includes a protrusion portion and a concave portion that are alternately disposed, and the electrode pattern includes a first electrode pattern disposed on one side of one of the plurality of sub-pixels and a second electrode pattern disposed on the other side of the one of the sub-pixels.

The organic light-emitting element comprises a first electrode; an organic light-emitting layer on the first electrode; and a second electrode on the organic light-emitting layer, wherein the organic light-emitting layer overlaps at least a portion of the protrusion portion and may not overlap the concave portion in a plan view.

The display apparatus further comprises a lens layer disposed on the electrode pattern, the first electrode pattern includes the first inner side in a plan view, and the second electrode pattern includes the second inner side in a plan view, the first inner side and the second inner side are disposed to face each other, the protrusion portion may include first protrusion portions disposed on the first inner side and second protrusion portions disposed on the second inner side, and the concave portion may include first concave portions disposed on the first inner side and second concave portions disposed on the second inner side.

The lens layer can cover the first inner side and the second inner side in a plan view.

The first protrusion portions and the second protrusion portions may be disposed to face each other, and the first concave portions and the second concave portions may be disposed to face each other.

The first protrusion portions and the first concave portions may be disposed alternately, and the second protrusion portions and the second concave portions may be disposed alternately.

When the direction connecting the first protrusion portions and the second protrusion portions with the shortest distance is referred to as a second direction, and a direction perpendicular to the second direction is referred to as a first direction, the organic light-emitting element includes: a first electrode; an organic light-emitting layer on the first electrode; and a second electrode on the organic light-emitting layer, and a maximum width of the organic light-emitting layer in a plane based on the second direction may be larger than the shortest distance between the first protrusion portions and the second protrusion portions, and smaller than the shortest distance between the first concave portions and the second concave portions.

A width of an area occupied by the lens layer in a plane based on the second direction may be greater than the shortest distance between the first concave portions and the second concave portions in a plane.

The first protrusion portions and the second protrusion portions can be disposed toward the organic light-emitting layer in a plan view.

The first concave portions and the second concave portions can be disposed toward the organic light-emitting layer in a plan view.

The display apparatus can further comprise a lens layer disposed on the electrode pattern, and lens layer can overlap the protrusion portion and the concave portion.

At least one of the first protrusion portions and at least one of the second protrusion portions can overlap an end of the organic light-emitting layer in a plan view.

The electrode pattern includes an electrode connecting portion connecting the first electrode pattern and the second electrode pattern, and the electrode connecting portion may not overlap with the organic light-emitting layer.

The lens layer may overlap the organic light-emitting layer in a plan view.

The display apparatus may further comprise a flat film disposed on the lens layer, the flat film has a lower refractive index than the lens layer.

When a direction connecting the first protrusion portions and the second protrusion portions with the shortest distance is referred to as a second direction, and a direction perpendicular to the second direction is referred to as a first direction, the length of each of the first protrusion portions and the length of each of the first concave portions may be the same with respect to the first direction, and the length of each of the second protrusion portions and the length of each of the second concave portions may be the same with respect to the first direction.

When a direction connecting the first protrusion portions and the second protrusion portions with the shortest distance is referred to as a second direction, and a direction perpendicular to the second direction is referred to as a first direction, wherein the length of each of the first protrusion portions is the same, the length of each of the first concave portions is the same, the length of each of the second protrusion portions is the same, and the length of each of the second concave portions is the same with respect to the first direction.

The plurality of sub-pixels include a first sub-pixel and a second sub-pixel disposed adjacent to each other, the organic light-emitting element includes a first organic light-emitting layer disposed in the first sub-pixel and a second organic light-emitting layer disposed in the second sub-pixel, the first organic light-emitting layer and the second organic light-emitting layer are disposed to be spaced apart from each other, the first electrode pattern is disposed on one side of the first sub-pixel, the second electrode pattern is disposed on the other side of the first sub-pixel, and the electrode pattern includes a third electrode pattern disposed on one side of the second sub-pixel and a fourth electrode pattern disposed on the other side of the second sub-pixel, and the second electrode pattern and the third electrode pattern are disposed between the first organic light-emitting layer and the second organic light-emitting layer in a plan view, and the second electrode pattern and the third electrode pattern can be spaced apart from each other.

The difference between the shortest distance between the first concave portions and the second concave portions and the shortest distance between the first protrusion portions and the second protrusion portions with respect to the second direction may be 1 to 3 μm.

The electrode pattern may be a touch electrode.

The electrode pattern may have a sawtooth shape.

Another exemplary embodiment of the present disclosure provides a display apparatus comprising: a substrate having a plurality of sub-pixels; an organic light-emitting element disposed on the substrate and including an organic light-emitting layer; and an electrode pattern disposed on the organic light-emitting element and including a protrusion portion and a concave portion that are alternately disposed, wherein the electrode pattern has a sawtooth shape, and wherein the organic light-emitting layer overlaps at least a portion of the protrusion portion and does not overlap the concave portion in a plan view.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram of a display apparatus according to one embodiment of the present invention.

FIG. 2 is a plan view showing a part of a display apparatus according to one embodiment of the present invention.

FIG. 3 is a cross-sectional view taken along line I-I′ of FIG. 2.

FIG. 4 is an enlarged view showing area A of FIG. 2.

FIG. 5 is an enlarged view showing a portion of a display apparatus according to another embodiment of the present invention.

FIG. 6 is an enlarged view showing a portion of a display apparatus according to another embodiment of the present invention.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION OF THE DISCLOSURE

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through the following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error band although there is no explicit description.

In describing a position relationship, for example, when the position relationship is described as ‘on’, ‘upon˜’, ‘above˜’, ‘below˜’ and ‘next to˜’, one or more portions may be disposed between two other portions unless ‘just’ or ‘direct’ is used. For example, where an element or layer is disposed “on” another element or layer, a third layer or element may be interposed therebetween.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the reference numerals to the components of each drawing describing embodiments of the present disclosure, the same components can have the same sign as can be displayed on the other drawings.

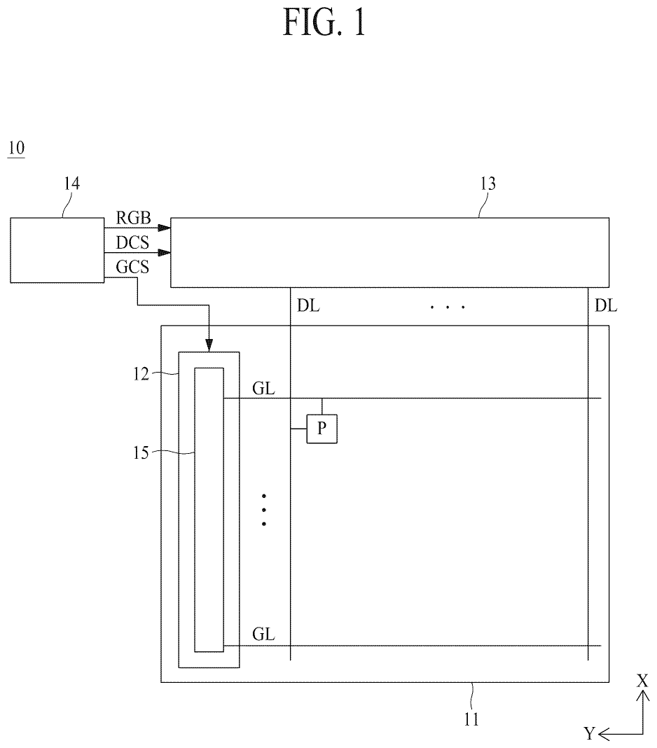

FIG. 1 is a schematic diagram of a display apparatus (10) according to one embodiment of the present invention.

The display apparatus (10) according to one embodiment of the present invention may include a display panel (11), a gate driver (12), a data driver (13), and a control unit (14), as shown in FIG. 1.

The display panel (11) includes gate lines (GL) and data lines (DL), and pixels (P) are disposed at intersections of the gate lines (GL) and data lines (DL). An image is displayed by driving the pixels (P). The gate lines (GL), data lines (DL), and pixels (P) may be disposed on a substrate (101).

The control unit (14) controls the gate driver (12) and the data driver (13).

The control unit (14) uses a signal supplied from an external system (not shown) to output a gate control signal (GCS) for controlling the gate driver (12) and a data control signal (DCS) for controlling the data driver (13). In addition, the control unit (14) samples input image data input from an external system, rearranges it, and supplies redisposed digital image data (RGB) to the data driver (13).

The gate control signal (GCS) includes a gate start pulse (GSP), a gate shift clock (GSC), a gate output enable signal (GOE), a start signal (Vst), and a gate clock (GCLK). In addition, the gate control signal (GCS) may include control signals for controlling a shift register.

Data control signals (DCS) include source start pulse (SSP), source shift clock signal (SSC), source output enable signal (SOE), and polarity control signal (POL).

The data driver (13) supplies data voltage to the data lines (DL) of the display panel (11). Specifically, the data driver (13) converts image data (RGB) input from the control unit (14) into analog data voltage and supplies the data voltage to the data lines (DL).

According to one exemplary embodiment of the present disclosure, the gate driver (12) may be mounted on the display panel (11). In this way, a structure in which the gate driver (12) is directly mounted on the display panel (11) is called a gate in panel (GIP) structure, but is not limited thereto. Specifically, in the gate in panel (GIP) structure, the gate driver (12) may be disposed on the substrate (101). The gate driver (12) may be connected to the substrate (101) in an example where the gate driver (12) is implemented by the chip-on-glass (COG) technique, the chip-on-film (COF) technique, or the like.

In one or more aspects, the gate driver (12) may be connected to the display panel (11) by the tape-automated-bonding (TAB) technique, or connected to a conductive pad such as a bonding pad of the display panel 110 by the chip-on-glass (COG) technique or the chip-on-panel (COP) technique, or connected to the display panel (11) by the chip-on-film (COF) technique.

The gate driver (12) may include a shift register (15).

The shift register (15) sequentially supplies gate pulses to the gate lines (GL) for one frame using a start signal and a gate clock transmitted from the control unit (14). Here, one frame refers to a period during which one image is output through the display panel (11). The gate pulse has a turn-on voltage capable of turning on a switching element (thin film transistor) disposed in a pixel (P).

In addition, the shift register (15) supplies a gate off signal capable of turning off the switching element to the gate line (GL) during the remaining period during which the gate pulse is not supplied during one frame. Hereinafter, the gate pulse and the gate off signal are collectively referred to as a scan signal (SS or Scan).

The pixels (P) can be disposed along each of the first direction (X) and the second direction (Y) transverse to the first direction (X).

Each pixel (P) may include a plurality of adjacent sub-pixels (SP). For example, the first direction (X) may be a first longitudinal direction, a long-side longitudinal direction, a horizontal direction, or a first horizontal direction of the substrate (101). For example, the second direction (Y) may be a second longitudinal direction, a short-side longitudinal direction, a vertical direction, a second horizontal direction, or a vertical direction of the substrate (101).

A plurality of sub-pixels (SP) may be disposed in the display area, and several types of signal lines for driving the plurality of sub-pixels (SP) may be disposed therein, without being limited thereto.

The non-display area may refer to an area outside of the display area. Several types of signal lines may be disposed in the non-display area, and several types of driving circuits may be connected thereto. The non-display area may be also referred to as an edge area or a bezel area.

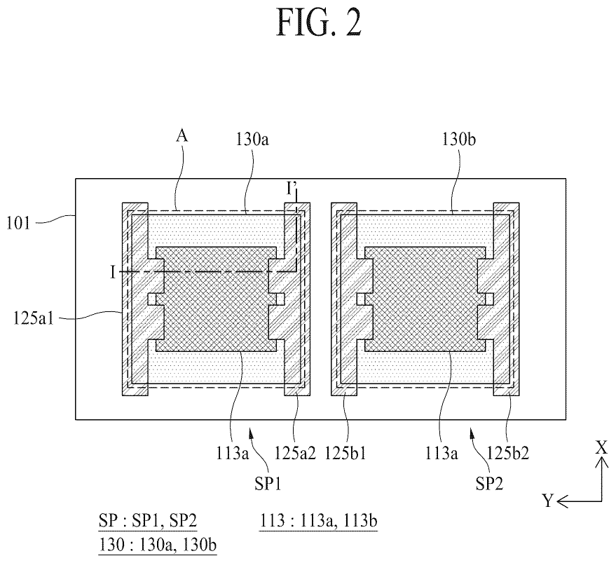

A pixel (P) may include a plurality of sub-pixels such as four sub-pixels. For example, the pixel (P) may include a first sub-pixel (SP1), a second sub-pixel (SP2), a third sub-pixel (SP3), and a fourth sub-pixel (SP4), but the embodiments of the present specification are not limited thereto. For example, FIG. 2 illustrates a pixel (P) including a first sub-pixel (SP1) and a second sub-pixel (SP2). More or less sub-pixels may be possible.

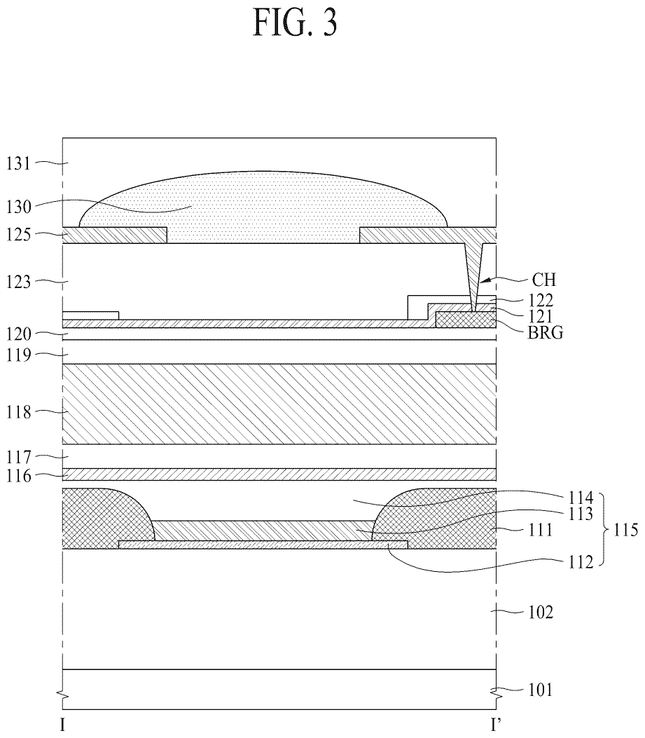

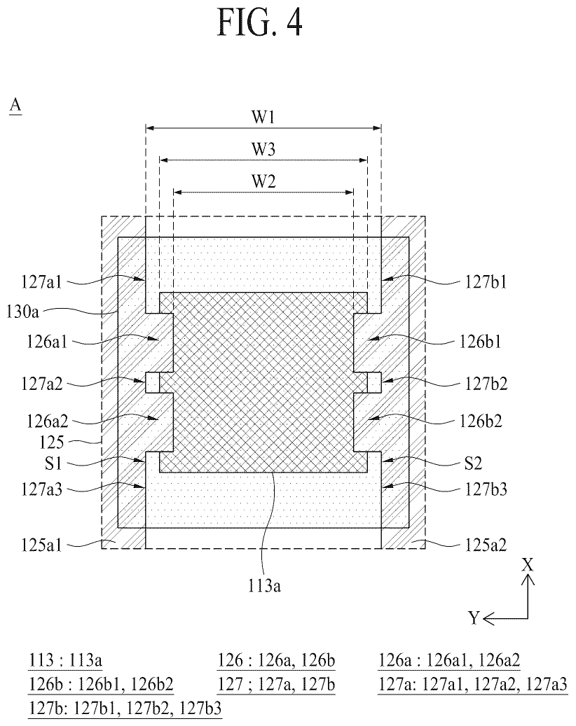

FIG. 1 is a schematic diagram of a display apparatus (10) according to one embodiment of the present invention. FIG. 2 is a plan view showing a part of a display apparatus (10) according to one embodiment of the present invention. FIG. 3 is a cross-sectional view taken along line I-I′ of FIG. 2. FIG. 4 is an enlarged view showing area A of FIG. 2 in an enlarged manner. Area ‘A’ of FIG. 2 is an area for a first sub-pixel (SP1). The description of the electrode pattern (125) disposed in the second sub-pixel (SP2) illustrated in FIG. 2 is omitted because it overlaps with the description of the electrode pattern (125) disposed in the first sub-pixel (SP1).

According to one embodiment of the present invention, a display apparatus (10) may include a substrate (101) having a plurality of sub-pixels (SP), a circuit element layer (102), an organic light-emitting element (115), an electrode pattern (125), and a lens layer (130). The components of the display apparatus are described in detail below.

Glass, plastic or flexible polymer film can be used as the substrate (101). A transparent plastic having flexible properties, such as polyimide, can be used as the plastic.

For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

According to one embodiment of the present invention, a circuit element layer (102) may be disposed on a substrate (101).

In the circuit element layer (102), circuit elements including various signal wires, thin film transistors, and capacitors are disposed for each sub-pixel (SP).

The signal wiring may include a gate line, a data line, a power line, and a reference line, and the thin film transistor may include a switching thin film transistor, a driving thin film transistor, and a sensing thin film transistor.

The switching thin film transistor is switched according to the gate signal supplied to the gate line and supplies the data voltage supplied from the data line to the driving thin film transistor.

The driving thin film transistor switches according to the data voltage supplied from the switching thin film transistor and generates data current from the power supplied from the power line.

The sensing thin film transistor senses the threshold voltage deviation of the driving thin film transistor, which causes image quality degradation, and supplies current from the driving thin film transistor to the reference line in response to a sensing control signal supplied from the gate line or a separate sensing line.

The capacitor serves to maintain the data voltage supplied to the driving thin film transistor for one frame, and is connected to the gate terminal and source terminal of the driving thin film transistor, respectively.

The circuit element layer (102) may additionally include a passivation layer for protecting the switching thin film transistor, the driving thin film transistor, and the sensing thin film transistor, and a planarization layer provided on the passivation layer.

Depending on circumstances, the passivation layer may be omitted when the planarization layer has a function of protecting the switching thin film transistor, the driving thin film transistor, and the sensing thin film transistor. For example, the planarization layer, which may be a kind of inorganic or organic dielectric, may be made of any one of photo acrylic, polyimide, benzocyclobutene resin, and acrylate, etc. According to one exemplary embodiment of the present disclosure, an organic light-emitting element (115) and a bank (111) may be disposed on a circuit element layer (102).

The organic light-emitting element (115) may include a first electrode (112), an organic light-emitting layer (113) on the first electrode (112), and a second electrode (114) on the organic light-emitting layer (113). The first electrode (112) may be an anode electrode, and the second electrode (114) may be a cathode electrode, but is not limited thereto. For example, the first electrode (112) may be a cathode electrode, and the second electrode (114) may be an anode electrode.

For example, the organic light-emitting layer (113) may include one or more of a hole injection layer (HIL), a hole transmitting layer (HTL), an electron transmitting layer (ETL) and an electron injection layer (EIL), but the present disclosure is not limited thereto.

The first electrode (112) may be connected to a thin film transistor in the circuit element layer (102) through a contact hole. The first electrode (112) may include a single-layer structure or a multi-layer structure made of one material selected from aluminum (Al), silver (Ag), molybdenum (Mo), gold (Au), magnesium (Mg), calcium (Ca), or barium (Ba), or two or more alloy materials. However, one embodiment of the present invention is not limited thereto.

The bank (111) may be formed to cover the edge of the first electrode (112) on the circuit element layer (102) to define a plurality of sub-pixels (SP). That is, the bank (111) serves as a pixel defining film that defines a plurality of sub-pixels (SP).

For example, the bank (111) may be made of an insulating material containing a black material. The bank (111) may be made of, for example, a transparent carbon-based mixture. Specifically, the bank (111) may contain carbon black, but is not limited thereto. The bank (111) may also be made of a transparent insulating material.

The first electrode (112) corresponding to the anode electrode, an organic light-emitting layer (113), and a second electrode (114) corresponding to the cathode electrode are sequentially laminated to represent a region where holes from the first electrode (112) and electrons from the second electrode (114) combine with each other in the organic light-emitting layer (113) to emit light. In this case, the region where the bank (111) is formed does not emit light and can therefore be defined as a non-light-emitting region.

The bank (111) can be formed of an organic film such as an acrylic resin, an epoxy resin, a phenolic resin, a polyamide resin, or a polyimide resin.

An organic light-emitting layer (113) is formed on the first electrode (112). The organic light-emitting layer (113) may be disposed between different banks (111). For example, the organic light-emitting layer (113) may be disposed to cover the side surface of banks (111) and the upper surface of the first electrode (112). The organic light-emitting layer (113) may also be formed by patterning. For example, the organic light-emitting layer (113) may include a first organic light-emitting layer (113a) disposed in a first sub-pixel (SP1) and a second organic light-emitting layer (113b) disposed in a second sub-pixel (SP2) (see FIG. 2). For example, the first organic light-emitting layer (113a) and the second organic light-emitting layer (113b) may be disposed to be spaced apart from each other (see FIG. 2).

The second electrode (114) may be disposed on the organic light-emitting layer (113). For example, the second electrode (114) may be disposed to cover the organic light-emitting layer (113) and the banks (111). The second electrode (114) is a common layer formed commonly in the pixels (P). The second electrode (114) may be formed of a transparent metal material (TCO) such as ITO or IZO that can transmit light, or a semi-transmissive metal material such as magnesium (Mg), silver (Ag), or an alloy of magnesium (Mg) and silver (Ag), but is not limited thereto.

An atomic deposition layer (116) may be disposed on the second electrode (114). The atomic deposition layer (116) is a film formed using an atomic layer deposition (ALD) technique, and since it is a method of forming by stacking atomic layers, a very thin film can be formed, and the thickness and composition of the film can be precisely controlled. Accordingly, a film can be uniformly formed even on a large-area substrate, and since the ability to cover steps (stack coverage) is excellent, by covering the surface of the second electrode (114) with the atomic deposition layer (116), the reliability of the organic light-emitting element (115) can be improved.

A plurality films such as first inorganic film (117), an organic film (118), and a second inorganic film (119) may be sequentially disposed on an atomic deposition layer (116), but is not limited thereto. More or less films may be possible. The first inorganic film (117), the organic film (118), and the second inorganic film (119) serve to prevent oxygen or moisture from penetrating into the second electrode (114). The first inorganic film (117), the organic film (118), and the second inorganic film (119) can prevent foreign substances (particles) from being introduced into the organic light-emitting layer (113) and the second electrode (114).

The first inorganic film (117) is disposed on the atomic deposition layer (116). The first inorganic film (117) can be formed to cover the atomic deposition layer (116).

The organic film (118) is disposed on the first inorganic film (117). The organic film (118) can be formed to cover the first inorganic film (117). The organic film (118) can be formed to a sufficient thickness to prevent foreign substances from penetrating the first inorganic film (117) and entering the organic light-emitting layer (113) and the second electrode (114).

The second inorganic film (119) is disposed on the organic film (118). The second inorganic film (119) can be formed to cover the organic film (118).

Each of the first inorganic film (117) and the second inorganic film (119) can be formed of silicon nitride, aluminum nitride, zirconium nitride, titanium nitride, hafnium nitride, tantalum nitride, silicon oxide, aluminum oxide, or titanium oxide.

A first buffer layer (120) may be disposed on the second inorganic film (119). The first buffer layer (120) can be formed to cover the second inorganic film (119). The first buffer layer (120) may have insulating properties. For example, the first buffer layer (120) may include at least one of silicon oxide (SiOx), silicon nitride (SiNx), and metal oxide having insulating properties.

A bridge metal (BRG) may be disposed on the first buffer layer (120). For example, the bridge metal (BRG) can be formed to cover a portion of the first buffer layer (120). The bridge metal (BRG) may be connected to the electrode pattern (125) through the contact hole (CH). Specifically, the bridge metal (BRG) may electrically connect a part of the electrode pattern (125) to another part. For example, the bridge metal (BRG) may electrically connect a first electrode pattern (125a1) to a second electrode pattern (125a2) (see FIG. 2). For example, the bridge metal (BRG) may overlap the electrode pattern (125). For example, the bridge metal (BRG) may not overlap the lens layer (130). For example, the bridge metal (BRG) may not overlap the organic light-emitting layer (113).

According to one exemplary embodiment of the present disclosure, a bridge metal (BRG) may be disposed at the edge of the electrode pattern (125). For example, the bridge metal (BRG) may be disposed to overlap the electrode pattern (125) at the edge of the electrode pattern (125).

A second buffer layer (121) may be disposed on the bridge metal (BRG). For example, the second buffer layer (121) may be disposed on the bridge metal (BRG) and the portion of the first buffer layer (120) exposed by the bridge metal (BRG). For example, the bridge metal (BRG) may be disposed between the first buffer layer (120) and the second buffer layer (121).

A black matrix (122) may be disposed on the second buffer layer (121). Specifically, referring to FIG. 3, the black matrix (122) may be disposed on a portion of the upper surface of the second buffer layer (121). For example, the black matrix (122) may overlap with the electrode pattern (125). For example, the black matrix (122) may not overlap with the lens layer (130). For example, the black matrix (122) may not overlap with the organic light-emitting layer (113).

A PAC layer (123) may be disposed on a black matrix (122). For example, the PAC layer (123) may be disposed on the black matrix (122) and the portion of the second buffer layer (121) exposed by the black matrix (122). The PAC layer (123) is formed on the entire surface of the substrate (101). The PAC layer (123) is formed of a polymer material that has excellent insulation properties and does not react with external substances. The PAC layer (123) covers the second buffer layer (121) and the bridge metal (BRG) so that they are not exposed to the outside. The PAC layer (123) can protect the second buffer layer (121) and the bridge metal (BRG) from external foreign substances such as moisture and oxygen.

An electrode pattern (125) may be disposed on the PAC layer (123). For example, the electrode pattern (125) may be formed to cover a portion of the PAC layer (123). For example, the electrode pattern (125) may be disposed on the organic light-emitting element (115). The electrode pattern (125) may be a touch electrode. For example, the electrode pattern (125) may be connected to another electrode pattern (125) through a bridge metal (BRG). The electrode pattern (125) may detect a touch position on the display area.

In general, in organic light-emitting displays, pixel shrinkage, in which the size of a pixel (P) decreases or the display area decreases due to high-temperature deterioration driving, may occur. This pixel shrinkage phenomenon may cause a difference in brightness between an area where deterioration occurs (deteriorated area) and an area where deterioration does not occur (non-deteriorated area). Specifically, as pixels shrink, brightness decreases at a specific viewing angle. Even if this brightness decrease is compensated for, compensation is not performed in the viewing angle direction, so the brightness of the deteriorated area may decrease compared to the non-deteriorated area.

To improve this brightness difference, the electrode pattern (125) may have a sawtooth shape. For example, the electrode pattern (125) may have protrusion portion (126) and concave portion (127). For example, the protrusion portion (126) and concave portion (127) may be disposed alternately.

According to one embodiment of the present invention, the protrusion portion (126) may refer to an area that protrudes from the electrode pattern (125) in a plane toward the organic light-emitting layer (113), and the concave portion (127) may refer to an area that does not protrude from the electrode pattern (125) in a plane toward the organic light-emitting layer (113) compared to the protrusion portion (126).

Specifically, the electrode pattern (125) may include a first electrode pattern (125a1) disposed on one side of one first sub-pixel (SP1) among a plurality of sub-pixels (SP) and a second electrode pattern (125a2) disposed on the other side of the first sub-pixel (SP1).

The first electrode pattern (125a1) may include a first inner side (S1) that faces the first organic light-emitting layer (113a) in a plan view, and the second electrode pattern (125a2) may include a second inner side (S2) that faces the first organic light-emitting layer (113a) in a plan view. The first inner side (S1) and the second inner side (S2) may be disposed to face each other.

According to one exemplary embodiment of the present disclosure, the protrusion portion (126) may include first protrusion portions (126a) disposed on the first inner side (S1) and second protrusion portions (126b) disposed on the second inner side (S2). For example, the protrusion portion (126) may include a plurality of first protrusion portions disposed on the first inner side (S1) and a plurality of second protrusion portions disposed on the second inner side (S2). For example, FIG. 4 illustrates two first protrusion portions (126a1, 126a2) disposed on the first inner side (S1) and two second protrusion portions (126b1, 126b2) disposed on the second inner side (S2), but is not limited thereto. More or less protrusion portions may be possible. Referring to FIG. 4, the direction connecting the first protrusion portions (126a) and the second protrusion portions (126b) at the shortest distance may be referred to as the second direction (Y), and the direction perpendicular to the second direction (Y) may be referred to as the first direction (X).

As one example, the first protrusion portions (126a) may include a plurality of protrusions, and the second protrusion portions (126b) may include a plurality of protrusions. Specifically, the first protrusion portions (126a) may include a first-first protrusion portion (126a1) and a first-second protrusion portion (126a2), and the second protrusion portions (126b) may include a second-first protrusion portion (126b1) and a second-second protrusion portion (126b2), but is not limited thereto.

For example, the first-first protrusion portion (126a1) and the first-second protrusion portion (126a2) are spaced apart from each other in the first direction (X), and the second-first protrusion portion (126b1) and the second-second protrusion portion (126b2) are spaced apart from each other in the first direction (X).

According to one exemplary embodiment of the present disclosure, the concave portion (127) may include first concave portions (127a) disposed on the first inner side (S1) and second concave portions (127b) disposed on the second inner side (S2). As one example, the concave portion (127) may include a plurality of first concave portions disposed on the first inner side (S1) and a plurality of second concave portions disposed on the second inner side (S2). For example, FIG. 4 illustrates a configuration in which three first concave portions (127a1, 127a2, 127a3) are disposed on the first inner side (S1) and three second concave portions (127b1, 127b2, 127b3) are disposed on the second inner side (S2), but is not limited thereto. FIG. 4 illustrates a configuration in which first protrusion portions (126a) are disposed between first concave portions (127a) and second protrusion portions (126b) are disposed between second concave portions (127b). For example, the first protrusion portions (126a) and the first concave portions (127a) may be disposed alternately, and the second protrusion portions (126b) and the second concave portions (127b) may be disposed alternately.

For example, the three first concave portions (127a1, 127a2, 127a3) are spaced apart from each other in the first direction (X), and the three second concave portions (127b1, 127b2, 127b3) are spaced apart from each other in the first direction (X).

Specifically, the first concave portions (127a) may include a first-first concave portion (127a1) and a first-second concave portion (127a2), and the second concave portions (127b) may include a second-first concave portion (127b1) and a second-second concave portion (127b2), but is not limited thereto. For example, the first concave portions (127a) may include a first-first concave portion (127a1), a first-second concave portion (127a2) and a first-third concave portion (127a3), and the second concave portions (127b) may include a second-first concave portion (127b1), a second-second concave portion (127b2) and a second-third concave portion (127b3).

When the electrode pattern (125) is formed in a sawtooth shape, the gap between the first electrode pattern (125a1) and the second electrode pattern (125a2) in the area where the protrusion portion (126) is formed decreases, so that the light profile in the area where the protrusion portion (126) is formed narrows, and the gap between the first electrode pattern (125a1) and the second electrode pattern (125a2) in the area where the concave portion (127) is formed increases, so that the light profile in the area where the concave portion (127) is formed widens. In other words, by alternately forming narrow and wide areas of the light profile, the difference in brightness between the deteriorated area and the non-deteriorated area can be reduced.

According to one exemplary embodiment of the present disclosure, the inner surface refers to a surface located inside or within the electrode pattern (125) based on one sub-pixel (SP). For example, it refers to a surface or inner surface facing the inside rather than the outside of the electrode pattern (125). According to the present disclosure, a pixel shrinkage phenomenon may occur in a region of the organic light-emitting layer (113) that is disposed toward the first inner side (S1) and the second inner side (S2) in a plan view.

According to one embodiment of the present invention, the first protrusion portions (126a) and the second protrusion portions (126b) may be disposed to face each other. For example, the first protrusion portions (126a) and the second protrusion portions (126b) may be disposed to face each other and face the organic light-emitting layer (113).

According to one embodiment of the present invention, the first concave portions (127a) and the second concave portions (127b) may be disposed to face each other. For example, the first concave portions (127a) and the second concave portions (127b) may be disposed to face each other and face the organic light-emitting layer (113).

According to one exemplary embodiment of the present disclosure, the first protrusion portions (126a) and the first concave portions (127a) may be disposed alternately in the first direction (X), and the second protrusion portions (126b) and the second concave portions (127b) are disposed alternately in the first direction (X).

According to one embodiment of the present invention, the organic light-emitting layer (113) may overlap at least a portion of the protrusion portion (126) in a plan view and may not overlap the concave portion (127) (see FIG. 4). For example, the protrusion portion (126) of the electrode pattern (125) may overlap the organic light-emitting layer (113).

Specifically, since the protrusion portion (126) overlaps the organic light-emitting layer (113) and the concave portion (127) does not overlap the organic light-emitting layer (113) in a plan view, the light profile can be narrowed in the area where the protrusion portion (126) is formed, and the light profile can be widened in the area where the concave portion (127) is formed. As a result, the difference in brightness between the deteriorated area and the non-deteriorated area can be reduced by alternately forming narrow and wide areas of the light profile.

According to one embodiment of the present invention, the maximum width (W3) of the organic light-emitting layer (113) in a plane may be larger than the shortest distance (W2) between the first protrusion portions (126a) and the second protrusion portions (126b) with respect to the second direction (Y), and smaller than the shortest distance (W1) between the first concave portions (127a) and the second concave portions (127b) (see FIG. 4). According to one embodiment of the present invention, the width may be a length or distance measured along a direction parallel to the second direction (Y).

In a plane, the shortest distance (W2) between the first protrusion portions (126a) and the second protrusion portions (126b) in the second direction (Y) is smaller than the maximum width (W3) of the organic light-emitting layer (113), and the shortest distance (W1) between the first concave portions (127a) and the second concave portions (127b) in the second direction (Y) is larger than the maximum width (W3) of the organic light-emitting layer (113), so that a wide light profile and a narrow light profile can be combined. As a result, the difference in brightness according to the viewing angle between the deteriorated area and the non-deteriorated area can be improved due to the pixel shrinkage phenomenon.

For example, the maximum width (W3) of the organic light-emitting layer (113) in a plane based on the second direction is larger than the shortest distance (W2) between the first protrusion portions (126a) and the second protrusion portions (126b), and smaller than a shortest distance (W1) between the first concave portions (127a) and the second concave portions (127b), but is not limited thereto.

According to one exemplary embodiment of the present disclosure, the difference between the shortest distance (W1) between the first concave portions (127a) and the second concave portions (127b) and the shortest distance (W2) between the first protrusion portions (126a) and the second protrusion portions (126b) with respect to the second direction (Y) may be 1 to 3 μm, but is not limited thereto.

When the difference between the shortest distance (W1) between the first concave portions (127a) and the second concave portions (127b) and the shortest distance (W2) between the first protrusion portions (126a) and the second protrusion portions (126b) with respect to the second direction (Y) is less than 1 μm, compensation in the viewing angle direction may not be sufficiently achieved. As a result, the difference in brightness between the deteriorated area and the non-deteriorated area may not be improved.

When the difference between the shortest distance (W1) between the first concave portions (127a) and the second concave portions (127b) and the shortest distance (W2) between the first protrusion portions (126a) and the second protrusion portions (126b) with respect to the second direction (Y) is greater than 3 μm, the brightness may increase excessively at a specific viewing angle or may not be cut-off at a specific viewing angle.

According to one embodiment of the present invention, the lens layer (130) can cover the first inner side (S1) and the second inner side (S2) in a plan view. FIG. 4 illustrates a configuration in which the lens layer (130) covers the first inner side (S1) and the second inner side (S2) in a plan view.

According to one embodiment of the present invention, the protrusion portions (126) and the concave portions (127) of the electrode pattern (125) may be disposed toward the organic light-emitting layer (113). For example, the first protrusion portions (126a) and the second protrusion portions (126b) of the protrusion portions (126) and the first concave portions (127a) and the second concave portions (127b) of the concave portion (127) may be disposed toward the organic light-emitting layer (113).

According to one embodiment of the present invention, the plurality of sub-pixels (SP) may include a first sub-pixel (SP1) and a second sub-pixel (SP2) (see FIG. 2).

Referring to FIG. 2, the organic light-emitting layer (113) may include a first organic light-emitting layer (113a) disposed in a first sub-pixel (SP1) and a second organic light-emitting layer (113b) disposed in a second sub-pixel (SP2). The first organic light-emitting layer (113a) and the second organic light-emitting layer (113b) may be disposed spaced apart from each other.

According to one embodiment of the present invention, the electrode pattern (125) may include a first electrode pattern (125a1) disposed on one side of the first sub-pixel (SP1) and a second electrode pattern (125a2) disposed on the other side of the first sub-pixel (SP1), and may include a third electrode pattern (125b1) disposed on one side of the second sub-pixel (SP2) and a fourth electrode pattern (125b2) disposed on the other side of the second sub-pixel (SP2).

For example, the first electrode pattern (125a1) and the second electrode pattern (125a2) may be disposed to face each other, and the third electrode pattern (125b1) and the fourth electrode pattern (125b2) may be disposed to face each other.

The third electrode pattern (125b1) may correspond to the first electrode pattern (125a1), and the fourth electrode pattern (125b2) may correspond to the second electrode pattern (125a2).

According to one exemplary embodiment of the present disclosure, the second electrode pattern (125a2) and the third electrode pattern (125b1) may be disposed between the first organic light-emitting layer (113a) and the second organic light-emitting layer (113b) in a plan view. The second electrode pattern (125a2) and the third electrode pattern (125b1) may be spaced apart from each other in the second direction (Y). For example, the second electrode pattern (125a2) and the third electrode pattern (125b1) may be disposed to face each other.

A lens layer (130) and a flat film (131) may be disposed on the electrode pattern (125). The lens layer (130) may overlap the organic light-emitting layer (113) in a plan view. The lens layer (130) may be formed in each of a plurality of sub-pixels (SP) to refract light. For example, the lens layer (130) may include a first lens layer (130a) disposed in a first sub-pixel (SP1) and a second lens layer (130b) disposed in a second sub-pixel (SP2). The first lens layer (130a) and the second lens layer (130b) may be disposed to be spaced apart from each other in the second direction (Y).

For example, the first lens layer (130a) may overlap the first organic light-emitting layer (113a), and the second lens layer (130b) may overlap the second organic light-emitting layer (113b).

Referring to FIGS. 2 and 3, the lens layer (130) may have a rectangular shape in a plan view, but may be a convex lens having a convex shape facing in the opposite direction of the substrate (101). Specifically, the lens layer (130) may have a semi-cylindrical column shape. When light is incident from the organic light-emitting layer (113), the lens layer (130) may refract the incident light with a refractive angle greater than the incident angle. Accordingly, the display apparatus (10) according to one embodiment of the present invention may have excellent light extraction efficiency.

A flat film (131) can be disposed on the lens layer (130). The flat film (131) can flatten the step caused by the lens layer (130).

The flat film (131) may have a lower refractive index than the lens layer (130). Specifically, the lens layer (130) may have a first refractive index, and the flat film (131) may have a second refractive index that is lower than the first refractive index. Accordingly, when light emitted from the organic light-emitting layer (113) is incident from the lens layer (130) to the flat film (131), the refractive angle may be refracted to a greater degree than the incident angle.

For example, the flat film (131) can be formed of an organic film such as an acrylic resin, an epoxy resin, a phenolic resin, a polyamide resin, a polyimide resin, or a poly acrylate, but is not limited thereto.

According to one embodiment of the present invention, the lens layer (130) may have a larger area in a planar view than the organic light-emitting layer (113). In FIG. 4, the lens layer (130) is illustrated as having a rectangular shape in a planar view, but the present invention is not limited thereto and may have various shapes.

According to one embodiment of the present invention, the lens layer (130) may overlap at least a portion of the electrode pattern (125). For example, in a planar view, the lens layer (130) may overlap the protrusion portions (126) and the concave portions (127) of the electrode pattern (125). FIG. 4 illustrates a first lens layer (130a) overlapping the first protrusion portions (126a), the second protrusion portions (126b), the first concave portions (127a), and the second concave portions (127b).

For example, the width of an area occupied by the lens layer (130) in a plane based on the second direction (Y) is greater than the shortest distance between the first concave portions (127a) and the second concave portions (127b) in a plane.

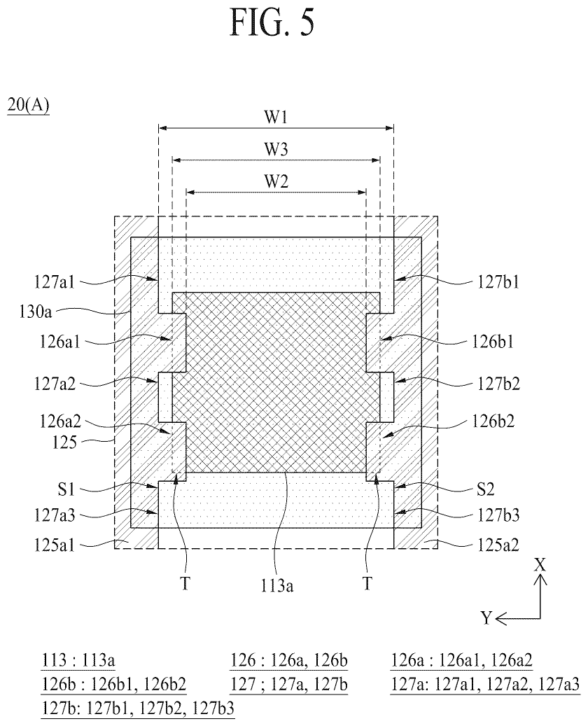

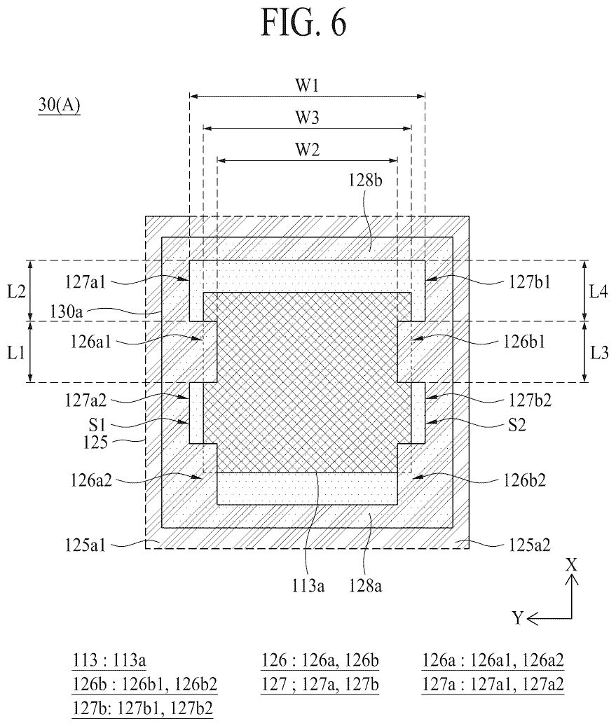

FIG. 5 is an enlarged view showing a part of a display apparatus (20) according to another embodiment of the present invention. FIG. 6 is an enlarged view showing a part of a display apparatus (30) according to another embodiment of the present invention. FIGS. 5 and 6 correspond to FIG. 4, which enlarges area A.

The display apparatus (20) shown in FIG. 5, compared to the display apparatus (10) shown in FIG. 4, has at least one of the first protrusion portions (126a) and at least one of the second protrusion portions (126b) overlapping with the end (T) of the organic light-emitting layer (113). According to the present disclosure, the end (T) may refer to the vertex of the organic light-emitting layer (113) in a planar view.

For example, FIG. 5 illustrates a configuration in which the first-second protrusion portion (126a2) and the second-second protrusion portion (126b2) overlap with the end (T) of the organic light-emitting layer (113) in a plan view. The present disclosure is not limited thereto, and either the first-second protrusion portion (126a2) or the second-second protrusion portion (126b2) may overlap with the end (T) of the organic light-emitting layer (113).

Compared to the display apparatus (10) shown in FIG. 4, the electrode pattern (125) of the display apparatus (30) shown in FIG. 6 includes an electrode connecting portion (128) that connects the first electrode pattern (125a1) and the second electrode pattern (125a2).

Referring to FIG. 6, the electrode connecting portion (128) may include a first electrode connecting portion (128a) and a second electrode connecting portion (128b). The first electrode connecting portion (128a) and the second electrode connecting portion (128b) may connect the first electrode pattern (125a1) and the second electrode pattern (125a2), respectively.

Referring to FIG. 6, the first electrode connecting portion (128a) and the second electrode connecting portion (128b) may be disposed in a direction perpendicular to the first electrode pattern (125a1) and the second electrode pattern (125a2). For example, the first electrode pattern (125a1) and the second electrode pattern (125a2) may be disposed in a direction parallel to the first direction (X), and the first electrode connecting portion (128a) and the second electrode connecting portion (128b) may be disposed along the second direction (Y) perpendicular to the first direction (X).

According to one embodiment of the present invention, the first electrode connecting portion (128a) and the second electrode connecting portion (128b) may not overlap the organic light-emitting layer (113) in a plane.

According to one embodiment of the present invention, the length of each of the first protrusion portions (126a) and the length of each of the first concave portions (127a) with respect to the first direction (X) may be the same. In addition, the length of each of the second protrusion portions (126b) and the length of each of the second concave portions (127b) with respect to the first direction (X) may be the same. In this case, the length of each of the first protrusion portions (126a) may be the same, the length of each of the first concave portions (127a) may be the same, the length of each of the second protrusion portions (126b) may be the same, and the length of each of the second concave portions (127b) may be the same with respect to the first direction (X). However, the present invention may not be limited thereto.

For example, FIG. 6 illustrates a configuration in which the length (L1) of the first-first protrusion portion (126a1) is the same as the length (L2) of the first-first concave portion (127a1) with respect to the first direction (X), and a configuration in which the length (L3) of the second-first protrusion portion (126b1) is the same as the length (L4) of the second-first concave portion (127b1) with respect to the first direction (X).

For example, the length of each of the first concave portions (127a) may be different, and the length of each of the second concave portions (127b) may be different. FIG. 4 illustrates a configuration in which the length of the first-first concave portion (127a1) is different from the length of the first-second concave portion (127a2) with respect to the first direction (X), the length of second-first concave portion (127b1) is different from the length of the second-second concave portion (127b2) with respect to the first direction (X), but is not limited thereto.

According to the present disclosure, the following advantageous effects may be obtained.

A display apparatus according to one embodiment of the present invention can improve the difference in brightness according to a viewing angle between a deteriorated area and a non-deteriorated area due to a pixel shrinkage phenomenon by controlling the shape of an electrode pattern.

In addition to the effects mentioned above, other features and advantages of the present invention are described below or may be clearly understood by those skilled in the art to which the present invention pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus comprising:
a substrate having a plurality of sub-pixels;
a circuit element layer disposed on the substrate;
an organic light-emitting element disposed on the circuit element layer; and
an electrode pattern disposed on the organic light-emitting element;
wherein the electrode pattern includes a protrusion portion and a concave portion that are alternately disposed, and
wherein the electrode pattern includes a first electrode pattern disposed on one side of one of the plurality of sub-pixels and a second electrode pattern disposed on the other side of the one of the plurality of sub-pixels.

2. The display apparatus of claim 1, wherein the organic light-emitting element comprises:
a first electrode;
an organic light-emitting layer on the first electrode; and
a second electrode on the organic light-emitting layer,
wherein the organic light-emitting layer overlaps at least a portion of the protrusion portion and does not overlap the concave portion in a plan view.

3. The display apparatus of claim 2, wherein the display apparatus further comprises a lens layer disposed on the electrode pattern,
wherein the first electrode pattern includes a first inner side in the plan view, and the second electrode pattern includes a second inner side in the plan view,
wherein the first inner side and the second inner side are disposed to face each other,
wherein the protrusion portion includes first protrusion portions disposed on the first inner side and second protrusion portions disposed on the second inner side, and
wherein the concave portion includes first concave portions disposed on the first inner side and second concave portions disposed on the second inner side.

4. The display apparatus of claim 3, wherein the lens layer covers the first inner side and the second inner side in the plan view.

5. The display apparatus of claim 3, wherein the first protrusion portions and the second protrusion portions face each other, and the first concave portions and the second concave portions face each other.

6. The display apparatus of claim 3, wherein the first protrusion portions and the first concave portions are disposed alternately, and the second protrusion portions and the second concave portions are disposed alternately.

7. The display apparatus of claim 3, wherein when a direction connecting the first protrusion portions and the second protrusion portions with the shortest distance is referred to as a second direction, and a direction perpendicular to the second direction is referred to as a first direction, wherein a maximum width of the organic light-emitting layer in a plane based on the second direction is larger than a shortest distance between the first protrusion portions and the second protrusion portions, and smaller than a shortest distance between the first concave portions and the second concave portions.

8. The display apparatus of claim 7, wherein a width of an area occupied by the lens layer in a plane based on the second direction is greater than the shortest distance between the first concave portions and the second concave portions in a plane.

9. The display apparatus of claim 3, wherein the first protrusion portions and the second protrusion portions are disposed toward the organic light-emitting layer in the plan view.

10. The display apparatus of claim 3, wherein the first concave portions and the second concave portions are disposed toward the organic light-emitting layer in a plan view.

11. The display apparatus of claim 1, wherein the display apparatus further comprises a lens layer disposed on the electrode pattern, and the lens layer overlaps the protrusion portion and the concave portion.

12. The display apparatus of claim 3, wherein at least one of the first protrusion portions and at least one of the second protrusion portions overlap an end of the organic light-emitting layer in the plan view.

13. The display apparatus of claim 3, wherein the electrode pattern includes an electrode connecting portion connecting the first electrode pattern and the second electrode pattern, and the electrode connecting portion does not overlap with the organic light-emitting layer.

14. The display apparatus of claim 3, wherein the lens layer overlaps the organic light-emitting layer in a plan view.

15. The display apparatus of claim 3, wherein the display apparatus further comprises a flat film disposed on the lens layer, the flat film has a lower refractive index than the lens layer.

16. The display apparatus of claim 13, wherein when a direction connecting the first protrusion portions and the second protrusion portions with the shortest distance is referred to as a second direction, and a direction perpendicular to the second direction is referred to as a first direction, wherein a length of each of the first protrusion portions and a length of each of the first concave portions are the same with respect to the first direction, and
wherein a length of each of the second protrusion portions and a length of each of the second concave portions are the same with respect to the first direction.

17. The display apparatus of claim 13, wherein when a direction connecting the first protrusion portions and the second protrusion portions with the shortest distance is referred to as a second direction, and a direction perpendicular to the second direction is referred to as a first direction, wherein the length of each of the first protrusion portions is the same, the length of each of the first concave portions is the same, the length of each of the second protrusion portions is the same, and the length of each of the second concave portions is the same with respect to the first direction.

18. The display apparatus of claim 14, wherein the plurality of sub-pixels include a first sub-pixel and a second sub-pixel disposed adjacent to each other,
wherein the organic light-emitting element includes a first organic light-emitting layer disposed in the first sub-pixel and a second organic light-emitting layer disposed in the second sub-pixel,
wherein the first organic light-emitting layer and the second organic light-emitting layer are spaced apart from each other,
wherein the first electrode pattern is disposed on one side of the first sub-pixel, the second electrode pattern is disposed on the other side of the first sub-pixel,
wherein the electrode pattern includes a third electrode pattern disposed on one side of the second sub-pixel and a fourth electrode pattern disposed on the other side of the second sub-pixel,
wherein the second electrode pattern and the third electrode pattern are disposed between the first organic light-emitting layer and the second organic light-emitting layer in the plan view, and
wherein the second electrode pattern and the third electrode pattern are spaced apart from each other.

19. The display apparatus of claim 7, wherein a difference between the shortest distance between the first concave portions and the second concave portions and the shortest distance between the first protrusion portions and the second protrusion portions with respect to the second direction is 1 to 3 μm.

20. The display apparatus of claim 1, wherein the electrode pattern is a touch electrode.

21. The display apparatus of claim 1, wherein the electrode pattern has a sawtooth shape.

22. A display apparatus comprising:
a substrate having a plurality of sub-pixels;
an organic light-emitting element disposed on the substrate and including an organic light-emitting layer; and
an electrode pattern disposed on the organic light-emitting element and including a protrusion portion and a concave portion that are alternately disposed,
wherein the electrode pattern has a sawtooth shape, and
wherein the organic light-emitting layer overlaps at least a portion of the protrusion portion and does not overlap the concave portion in a plan view.
